(19) United States
(12) Patent Application Publication
(10) Pub. No.: US 2005/0244725 A1
(43) Pub. Date: Nov. 3, 2005

(54) Apparatus and method for structure exposure of a photoreactive layer

(75) Inventor: Ralph Stommer, Neubiberg (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/120,660

(22) Filed: May 2, 2005

(30) Foreign Application Priority Data
Apr. 30, 2004 (DE) 10 2004 021 415.8

(51) Int. Cl. G06F 17/50; G03B 27/42; G03C 5/00; G03F 9/00

(52) U.S. Cl. 430/5; 355/53; 716/19; 716/21

(57) ABSTRACT

Exposure apparatus for structure exposure of a photoreactive material of a photoreactive layer with electromagnetic radiation, having a radiation source of electromagnetic radiation at a predetermined wavelength λ, a mask device in a form of a plate and having input and output faces for electromagnetic radiation. The mask device has a mask structure element composed of a mask material, which has a predetermined refractive index n_{core} at the wavelength of the electromagnetic radiation, and a surrounding material which is adjacent to surfaces of the mask structure element, which run essentially at right angles to an x direction and have a refractive index n_{xclad} at the predetermined wavelength, with the x direction being a predetermined direction parallel to a plate level of the mask device, and having predetermined mathematical relationships between the variables n_{core}, n_{xclad}, λ and d_{xcore}, with d_{xcore} being the extent of the mask structure element in the x direction.

### CROSS-REFERENCE TO RELATED APPLICATION

This application claims priority to German Patent Application Serial No. 10 2004 021 415.8, filed Apr. 30, 2004, and which is incorporated herein by reference in its entirety.

### FIELD OF THE INVENTION

The present invention relates to a method for structure exposure of a photoreactive layer, and an associated exposure apparatus.

### BACKGROUND OF THE INVENTION

In structuring methods and conventional lithography methods, such as those which are used in the semiconductor industry, the lateral resolution of structures such as MOSFET structures, trenches, metal lines and contact holes is restricted primarily by the wavelength λ which is used for development of a photoresist on a semiconductor wafer. Further influencing variables are the numerical aperture NA of the optical system, which numerical aperture NA receives the diffraction orders of a mask and images them on the resist to be exposed, and the so-called resolution factor k₁ which is governed by the order of the received diffraction orders.

The smallest possible lateral structure dₘᵢₙ is calculated to be

$${d}_{min} = {k}_{1} \cdot \frac{λ}{NA}$$

where NA is the numerical aperture of the projection optics and is defined by NA=n·sinΘₘₐₓ, where sinΘₘₐₓ is the maximum received beam half-angle of the projection optics and n is the refractive index of the surrounding medium. If the surrounding medium is air, then n≈1.

A resolution factor of k₁=0.25 can be achieved using conventional methods, for example using so-called scattering bars and phase shifter masks (PSM), on the assumption that the photoresist is “perfect”, that is to say it does not restrict the resolution, and that a so-called phase edge mask is used. With a maximum numerical aperture of NA=0.75 and at a wavelength of λ=193 nm, which corresponds to the wavelength of a conventional ArF Excimer laser, a minimum structure size down to dₘᵢₙ=64 nm can be produced. With a maximum numerical aperture of NA=0.85 and at a wavelength of λ=157 nm, which corresponds to the wavelength of an F₂ Excimer laser which may possibly be used, it is possible to produce structures down to a minimum size of dₘᵢₙ=46 nm.

The PSM technology as it was originally developed for simple structures such as periodic gratings in order to reduce the value of the resolution factor k₁, that is to say in order to reduce the minimum structure size dₘᵢₙ, is very complicated. At the moment, different PSM technologies are combined, in which case it is difficult with a large number of such complex mask arrangements to delete 0-order diffraction components. Furthermore, the production of such masks, in particular for a combination of different mask technologies, is highly complex with, inter alia, additional production steps being required, so that the production process is time consuming and expensive.

### SUMMARY OF THE INVENTION

One object of the invention is thus to produce structures which are as small as possible easily and at low cost and, in particular, to specify a corresponding method for structure exposure of a photoreactive layer, as well as an exposure apparatus.

The present invention provides a method for structure exposure of a photoreactive layer with electromagnetic radiation, composed of a photoreactive material, having the following steps:
provision of a radiation source of electromagnetic radiation at a predetermined wavelength λ;
provision of the photoreactive layer;
provision of a mask device, which is essentially in the form of a plate with an input face and an output face for electromagnetic radiation, with the mask device being arranged in the beam path between the radiation source and the photoreactive layer, with:
the mask device having at least one mask structure element composed of a mask material,
the mask material having a predetermined refractive index n_{core} at the wavelength λ of the electromagnetic radiation, and
a surrounding material being adjacent to surfaces of the at least one mask structure element which run essentially at right angles to an x direction and having a refractive index n_{xclad} at the predetermined wavelength λ of the electromagnetic radiation, with the x direction being a predetermined direction parallel to a plate level of the mask device which is in the form of a plate, and the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = {k}_{xcore} tan ( {k}_{xcore} \frac{{d}_{xcore}}{2} )$$
or the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = \frac{- {k}_{xcore}}{tan ( {k}_{xcore} \frac{{d}_{xcore}}{2} )}$$
essentially being applicable, where k_{xcore} is the real part of a complex wave vector of the electromagnetic radiation in the mask material in the x direction, \overline{k}_{xclad} is the imaginary part of a complex wave vector of the electromagnetic radiation in the surrounding material in the x direction, and d_{xcore} is the extent of the mask structure element in the x direction;
illumination of the input face of the mask device with the electromagnetic radiation; and
structure exposure of the photoreactive layer with electromagnetic radiation which emerges from the output face of the mask device.

### BRIEF DESCRIPTION OF THE DRAWINGS

The invention will be described, by way of example, in the following text on the basis of the accompanying drawings of preferred embodiment variants, with fundamental physical relationships also being explained in detail, in order to assist understanding. In the figures:

FIG. 1 shows a detail of a section view of a mask device as is used according to one preferred embodiment variant of the present invention;

FIG. 2 shows a schematic view of a wave vector of electromagnetic radiation, as is used according to one preferred embodiment variant of the method according to the present invention;

FIGS. 3a and 3b show a schematic profile of the electrical field of the electromagnetic radiation in the mask device;

FIG. 4 shows a detailed, schematic view of the diffraction of electromagnetic radiation as it passes through a conventional binary mask;

FIG. 5a shows a schematic view of the diffraction of electromagnetic radiation as it passes through a conventional binary mask;

FIG. 5b shows the distribution of the Fourier components of the diffraction of the electromagnetic radiation as it passes through a conventional binary mask;

FIG. 5c shows the image function of electromagnetic radiation after passing through a conventional binary mask;

FIG. 5d shows the intensity distribution of the electromagnetic radiation after passing through a conventional binary mask;

FIG. 6a shows a schematic view of the diffraction of electromagnetic radiation at it passes through a conventional phase shifter mask;

FIG. 6b shows the distribution of the Fourier components of the diffraction of the electromagnetic radiation after passing through a conventional phase shifter mask;

FIG. 6c shows the image function of electromagnetic radiation after passing through a conventional phase shifter mask;

FIG. 6d shows the intensity distribution of the electromagnetic radiation after passing through a conventional phase shifter mask;

FIGS. 7a and 7b show a schematic illustration of the electrical field of electromagnetic radiation in a mask structure element, and the surrounding material which is adjacent to it;

FIGS. 8a and 8b show the representation of \overline{k}_{xclad} as a function of k_{xcore};

FIG. 9 shows a schematic illustration of one preferred embodiment of an exposure apparatus for the present invention;

FIG. 10 shows the normalized intensity distribution of electromagnetic radiation as it passes through a mask structure element, as is used in one preferred embodiment variant of the method according to the present invention, and the normalized intensity distribution of a conventional phase shifter mask; and

FIG. 11 shows the normalized intensity distribution of electromagnetic radiation as it passes through a mask structure element, as is used in one preferred embodiment variant of the method according to the present invention, as well as the representation of this intensity profile when the dimensions of this mask structure element are varied.

### DETAILED DESCRIPTION OF PREFERRED EMBODIMENTS OF THE INVENTION

The present invention provides a method for structure exposure of a photoreactive layer with electromagnetic radiation, composed of a photoreactive material, having the following steps:
provision of a radiation source of electromagnetic radiation at a predetermined wavelength λ;
provision of the photoreactive layer;
provision of a mask device, which is essentially in the form of a plate with an input face and an output face for electromagnetic radiation, with the mask device being arranged in the beam path between the radiation source and the photoreactive layer, with:
the mask device having at least one mask structure element composed of a mask material,
the mask material having a predetermined refractive index n_{core} at the wavelength λ of the electromagnetic radiation, and
a surrounding material being adjacent to surfaces of the at least one mask structure element which run essentially at right angles to an x direction and having a refractive index n_{xclad} at the predetermined wavelength λ of the electromagnetic radiation, with the x direction being a predetermined direction parallel to a plate level of the mask device which is in the form of a plate, and the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = {k}_{xcore} tan ( {k}_{xcore} \frac{{d}_{xcore}}{2} )$$
or the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = \frac{- {k}_{xcore}}{tan ( {k}_{xcore} \frac{{d}_{xcore}}{2} )}$$
essentially being applicable, where k_{xcore} is the real part of a complex wave vector of the electromagnetic radiation in the mask material in the x direction, \overline{k}_{xclad} is the imaginary part of a complex wave vector of the electromagnetic radiation in the surrounding material in the x direction, and d_{xcore} is the extent of the mask structure element in the x direction;
illumination of the input face of the mask device with the electromagnetic radiation; and
structure exposure of the photoreactive layer with electromagnetic radiation which emerges from the output face of the mask device.

The method according to the present invention has the advantage that the mask devices which are used can be produced relatively easily, in particular in comparison to phase shifter masks. In particular, the method of the present invention has the advantage that the size of the mask device in the z direction is essentially negligible or non-critical. The z direction is in this case a direction which is essentially at right angles to the mask device, which is essentially in the form of a plate. The imaging characteristics of the mask device are governed essentially only by the lateral extent (extent on the xy plane, that is to say on the plate plane of the mask device which is in the form of a plate) of the mask structure elements to be imaged. However, when using modern lithographic techniques, for example when using electron beam lithography for mask production, lateral extents on the plate plane can be monitored excellently.

With conventional phase shifter masks, in contrast, the size of the phase shifter structures in the z direction is the critical variable, since this dimension is responsible for the necessary interference on the resist plane. Therefore in the case of phase shifter masks, the z dimension of the mask structure elements is that dimension which must be produced with the minimum possible tolerance. Even with modern semiconductor process techniques, however, the z direction (the direction at right angles to the processed semiconductor wafer) is considerably more difficult to monitor than the x direction and y direction.

There is therefore a fixed relationship between the extent of the mask structure elements, for example, in the x direction and the difference in the refractive index n_{core}-n_{xclad} between the refractive index n_{core} of the at least one mask structure element and the refractive index n_{xclad} in the x direction of the surrounding material, for a predetermined wavelength λ. In the method according to the present invention, electromagnetic radiation in consequence propagates through the mask structure element essentially in the same way as through a waveguide, while in contrast electromagnetic radiation is essentially exponentially attenuated in the surrounding material. The mask device in the present invention is thus a “waveguide mask” and is based on a fundamentally different physical basic principle than conventional binary or phase shifter masks.

It should be noted that k_{xcore}=0 does not represent a solution to the above relationship. The 0-order diffraction order is thus blocked owing to the characteristics of the mask device when the electromagnetic radiation passes through the at least one mask structure element. This leads to a resolution improvement by means of suitable choice of material and dimensioning of the at least one mask structure element and of the surrounding material.

The above relationships have been described using Cartesian coordinates. These relationships apply analogously using any desired coordinate system. For example, the above relationships can also be represented in polar coordinates. Use of a different coordinate system is, for example, worthwhile and/or necessary in the event of changed material isotropy characteristics of the at least one mask structure element or of the surrounding material, and/or, for example, when using a polarized electromagnetic wave and/or, for example, when the extent in the x direction d_{xcore} of the at least one mask structure element, that is to say the shape of the at least one mask structure element in the x direction, is not constant.

Furthermore, after studying this application, the responsible person skilled in the art will be aware that the above relationships would need to be modified appropriately for an anisotropic material and polarized electromagnetic waves, with the 0 diffraction order being blocked in each case.

In consequence, the method according to the present invention can make use of mask devices which have wider tolerance bands in the dimensions along the z direction than conventional phase shifter masks, and can thus be produced more reproducibly, more easily and at a lower cost.

The above considerations between the refractive index difference, the extent of the mask structure elements, the wavelength and the wave vector of the electromagnetic radiation are based on the assumption that the areas of the illuminated surrounding material on the xy plane do not exceed an extent of a few multiples of the wavelength λ of the incident radiation. In this case, the transmission characteristics of the mask device are dominated by its waveguide characteristics, so that effects of classical geometric optics are essentially negligible.

If, however, adjacent mask structure elements in the x direction are in some cases further away from one another than a few wavelengths λ, that is to say larger cohesive surface areas of the surrounding material on the xy plane are being illuminated, a cover device is preferably used.

For this purpose, a cover device is preferably fitted at least in places to a surface of the mask device which is adjacent to a mask structure element, which cover device is essentially opaque for the electromagnetic radiation. The cover device may be arranged between the surrounding material and the surface of the mask device.

It is particularly preferable for the cover device to be adjacent to the at least one mask structure element.

The input face of the mask device, which is in the form of a plate, can thus preferably be illuminated essentially completely with electromagnetic radiation. If, by way of example, electromagnetic radiation strikes the areas essentially between the mask structure elements, then these areas are preferably covered with a preferably thin layer of a material, with this layer preferably running essentially parallel to the plate plane of the mask device, which is in the form of a plate. The material is essentially opaque to the electromagnetic radiation.

The cover device is preferably a thin layer which extends essentially on the xy plane and is composed of a material which is opaque for the electromagnetic radiation. The cover device is in this case arranged in the beam path of the electromagnetic radiation, preferably upstream of the surrounding material. The cover device thus preferably has essentially the same cross-sectional shape as the surrounding material, at least in places, in a cross section parallel to the xy plane. In consequence, openings which correspond essentially to the mask structure elements are preferably arranged in one direction in the cover device.

If the cover device is not adjacent to the at least one mask structure element, then the maximum permissible separation between the at least one mask structure element and the cover device may be dependent on numerous factors. For example, the distance between the cover device and the at least one mask structure element may be dependent on the refractive index n_{core} of the mask structure element, on the refractive index n_{xclad} of the surrounding material, on the wavelength λ of the incident electromagnetic radiation, on the geometry of the mask structure element and/or on other factors. The maximum permissible distance between the at least one mask structure element and the cover element must thus be determined on an individual basis.

In one preferred embodiment variant of the method according to the present invention, a surrounding material is adjacent to surfaces of the at least one mask structure element which run essentially at right angles to a y direction, which surrounding material has a refractive index n_{yclad} at the predetermined wavelength λ of the electromagnetic radiation with the y direction being a predetermined direction essentially at right angles to the x direction and essentially parallel to the plane of the plate of the mask device which is in the form of a plate, and the principal relationships

$${n}_{core} > {n}_{yclad} , \\ {\overline{k}}_{yclad} = \sqrt{{( \frac{2 π}{λ} )}^{2} ( {n}_{core}^{2} - {n}_{yclad}^{2} ) - {k}_{ycore}^{2}} and$$

$${\overline{k}}_{yclad} = {k}_{ycore} tan ( {k}_{ycore} \frac{{d}_{ycore}}{2} )$$

or the principal relationships

$${n}_{core} > {n}_{yclad} , \\ {\overline{k}}_{yclad} = \sqrt{{( \frac{2 π}{λ} )}^{2} ( {n}_{core}^{2} - {n}_{yclad}^{2} ) - {k}_{ycore}^{2}} and$$

$${\overline{k}}_{yclad} = \frac{- {k}_{ycore}}{tan ( {k}_{ycore} \frac{{d}_{ycore}}{2} )}$$
essentially being applicable, where
k_{ycore} is the real part of a complex wave vector of the electromagnetic radiation in the mask material in the y direction,
\overline{k}_{yclad} is the imaginary part of a complex wave vector of the electromagnetic radiation in the surrounding material in the y direction, and
d_{ycore} is the extent of the mask structure element in the y direction.

It is advantageously also possible to consider the characteristics of the electromagnetic radiation which propagates through the mask structure element independently of one another in the x direction and y direction. In consequence, the dimensions in the x direction and y direction may be determined independently of one another, that is to say the above relationships for the dimension d_{xcore} and for the dimension d_{ycore} are applicable independently of one another. It is thus possible for two-dimensional structures to be imaged or produced, in which case the dimensions along the x direction and y direction can in each case be chosen essentially independently of one another.

The same considerations, characteristics and advantages of the invention apply in the same sense to the y direction as to the x direction.

The mask device preferably has a large number of mask structure elements.

In one preferred embodiment variant of the method according to the present invention, those surfaces of the mask structure element which run essentially at right angles to the y direction are essentially parallel to one another.

Those surfaces of the mask structure element which run essentially at right angles to the x direction are particularly preferably essentially parallel to one another.

The mask structure element preferably has an essentially rectangular cross section on a plane at right angles to the x direction.

In a further preferred embodiment variant of the method according to the present invention, the mask structure element has an essentially rectangular cross section on a plane at right angles to the y direction.

Furthermore, the mask structure element is preferably essentially cuboid.

The preferred embodiment variant of the method according to the present invention advantageously makes it possible to form two-dimensional structures which are each essentially rectangular, with the additional possibility of mask structure elements at least essentially partially overlapping when there are a large number of them. Furthermore, mask structure elements may also preferably contain subareas of other mask structure elements. For example, it is possible for two mask structure elements which each have an essentially rectangular cross section along the xy plane to form a mask structure element with an essentially L-shaped cross section on this plane.

Furthermore, the mask structure element preferably has an essentially circular cross section on a section plane parallel to the plate plane, and d_{xcore} is essentially equal to the diameter of the circular cross section. It is particularly preferable for d_{ycore} to be essentially equal to the diameter of the circular cross section.

In one preferred embodiment variant of the method according to the present invention, at least two mask structure elements merge at least partially into one another.

This advantageously allows a large number of different structures to be imaged on the basis of combinations of different individual structures.

It is particularly preferable for the surrounding material to be air. This allows the mask structure element to be designed to be particularly simple. In consequence, it is possible to carry out this preferred embodiment variant of the method according to the present invention at low cost.

The photoreactive layer is preferably a photoresist layer.

Furthermore d_{ycore} is preferably between about 5=m and about 100 nm for maximum resolution. The magnitude of d_{ycore} depends essentially on n_{ycore}, n_{yclad} and λ.

It is particularly preferable for d_{xcore} to be between about 5 nm and about 100=m for maximum resolution. The magnitude of d_{xcore} depends essentially on n_{xcore}, n_{xclad} and λ.

By way of example, a minimum magnitude is obtained for d_{xcore} or d_{ycore} for n_{xcore}=n_{ycore}=1.5 and n_{xclad}=n_{yclad}=nₐᵢᵣ=1 for λ=193=m: 10 nm≦d_{xcore}≦90 nm (and 10 nm≦d_{ycore}≦90 nm) and for λ=157 nm: 5 nm≦d_{xcore}≦70 nm (and 5 nm≦d_{ycore}≦70 nm).

The dimensions of d_{xcore} and d_{ycore} may, of course, also be greater, as in the case of conventional masks.

If maximum resolution is not necessary, for example structures (metallizations, steps, trenches) with sizes for more than 60 nm, in the μm range or even in the mm range, then d_{ycore} and d_{xcore} may also have dimensions of more than 100 nm in the μm range or even in the mm range, as in the case of conventional masks.

The radiation source is particularly preferably a radiation source for monochromatic electromagnetic radiation. By way of example, it is preferably a laser.

Furthermore, the extent of the mask device on the plate plane is considerably greater, in particular more than 100 times greater, than in the direction at right angles to it.

In a further preferred embodiment variant of the method according to the present invention, the surrounding material surrounds the mask material with a thickness which corresponds essentially to the thickness of the mask material.

In a further preferred embodiment variant of the present invention, electromagnetic radiation is supplied essentially at right angles to the input face of the mask device, which is in the form of a plate. The incident radiation direction of the light is essentially parallel to the z direction, and is in consequence essentially at right angles to the xy plane.

In a further preferred embodiment variant of the method according to the present invention, the light is incident in the form of a planar wave on the input face of the mask device, which is essentially in the form of a plate.

A further aspect of the present invention is the use of a mask device for structure exposure of a photoreactive layer composed of a photoreactive material, with electromagnetic radiation,
with the mask device
being essentially in the form of a plate,
having an input face and an output face for electromagnetic radiation,
being arranged in the beam path between a radiation source of electromagnetic radiation at a predetermined wavelength λ, and the photoreactive layer, and
having at least one mask structure element composed of a mask material, with
the mask material having a predetermined refractive index n_{core} at the wavelength λ of the electromagnetic radiation,
being adjacent to a surrounding material on surfaces of the at least one mask structure element which run essentially at right angles to an x direction, which surrounding material has a refractive index n_{xclad} at the predetermined wavelength λ of the electromagnetic radiation, with the x direction being a predetermined direction parallel to a plate level of the mask device which is in the form of a plate, and the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = {k}_{xcore} tan ( {k}_{xcore} \frac{{d}_{xcore}}{2} )$$
or the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = \frac{- {k}_{xcore}}{tan ( {k}_{xcore} \frac{{d}_{xcore}}{2} )}$$
essentially being applicable, where
k_{xcore} is the real part of a complex wave vector of the electromagnetic radiation in the mask material in the x direction,
\overline{k}_{xclad} is the imaginary part of a complex wave vector of the electromagnetic radiation in the surrounding material in the x direction, and
d_{xcore} is the extent of the mask structure element in the x direction.

A next aspect of the present invention relates to an exposure apparatus for structure exposure of a photoreactive material of a photoreactive layer with electromagnetic radiation, comprising:
a radiation source of electromagnetic radiation at a predetermined wavelength λ;
a mask device which is essentially in the form of a plate and having an input face and an output face for electromagnetic radiation, with:
the mask device having at least one mask structure element composed of a mask material,
the mask material having a predetermined refractive index n_{core} at the wavelength λ of the electromagnetic radiation, and
a surrounding material being adjacent to surfaces of the at least one mask structure element which run essentially at right angles to an x direction and having a refractive index n_{xclad} at the predetermined wavelength λ of the electromagnetic radiation, with the x direction being a predetermined direction parallel to a plate level of the mask device which is in the form of a plate, and the principal relationships:

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = {k}_{xcore} tan ( {k}_{xcore} \frac{{d}_{xcore}}{2} )$$
or the principal relationships

$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} and$$

$${\overline{k}}_{xclad} = \frac{- {k}_{xcore}}{tan ( {k}_{xcore} \frac{{d}_{xcore}}{2} )}$$
essentially being applicable, where
k_{xcore} is the real part of a complex wave vector of the electromagnetic radiation in the mask material in the x direction,
\overline{k}_{xclad} is the imaginary part of a complex wave vector of the electromagnetic radiation in the surrounding material in the x direction, and
d_{xcore} is the extent of the mask structure element in the x direction.

With regard to particular embodiments of the exposure apparatus according to the invention and of the use according to the invention of the mask device, reference should be made to the corresponding description of the method according to the invention above.

Preferred embodiment variants of the method according to the present invention will be described in detail in the following text with reference to the attached drawings. Fundamental physical relationships, which are helpful to easier understanding of the invention, will be described first of all.

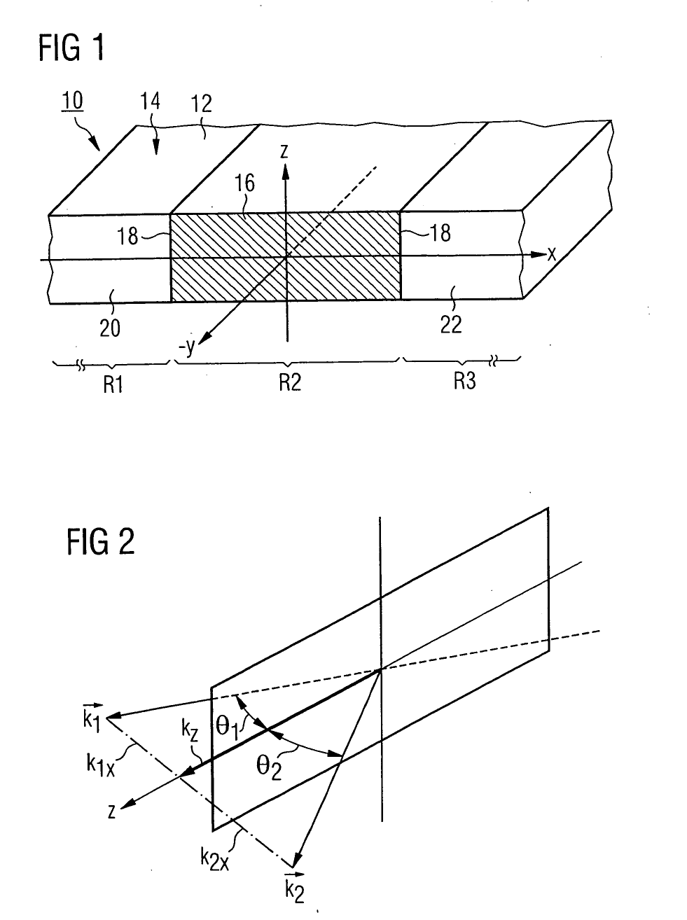

FIG. 1 shows a section view of a detail of a mask device 10. An x direction and a y direction cover an xy plane. The xy plane is essentially parallel to a plate plane 12 of the mask device 10, which is essentially in the form of a plate. The mask device 10 has an input face 14 and/or an output face (not shown) opposite the input face 14. A z direction is essentially at right angles to the xy plane. Electromagnetic radiation is preferably incident on the plate plane 12 essentially parallel to the z direction.

A mask structure element 16 which has a refractive index n_{core} is also illustrated. Surfaces 18 of the mask structure element 16 which run at right angles to the x direction are each adjacent to a surrounding material 20, 22. The surrounding material 20, 22 has a refractive index n_{xclad}. The illustration does not show a surrounding material which is adjacent to surfaces 24 which run at right angles to the y direction. This surrounding material has a refractive index n_{yclad}. Frequently n_{xclad}=n_{yclad}.

In order to assist understanding, the following description of the invention ignores the y direction and n_{xclad} is replaced by n_{clad}. The following description can be applied analogously to the dimension in the y direction, in which case n_{xclad} and n_{yclad} can, in principle, assume different values. The mask structure element 16 illustrated in FIG. 1 essentially shows a waveguide for electromagnetic radiation, in conjunction with the surrounding material, 20, 22.

In order to assist understanding of the invention, the following text describes characteristics of a waveguide. The waveguide shown in FIG. 1 has three mutually adjacent regions. In the x direction, a core region R2 is adjacent to surrounding regions R1 and R3 on opposite side surfaces. As shown in FIG. 1, the mask structure element 16 corresponds to the core region R2. The surrounding material 20 corresponds to the surrounding region R1, and the surrounding material 22 corresponds to the surrounding region R3. The core region R2 has a refractive index n₂, and the surrounding regions R1 and R2 have a refractive index n₁. The value of the refractive index n₂ of the core region R2 corresponds to the value of the refractive index n_{core} of the mask structure element, and the value of the refractive index n1 of the surrounding regions R1 and R3 corresponds to the value of the refractive index n_{clad} of the surrounding material.

The extent d₀ of the core region R2 in the x direction corresponds to the extent d_{xcore} of the mask structure element 16 in the x direction.

The wave differential equation in a waveguide is:

$$Δ Ψ ( \vec{r} , t ) - \frac{{n}^{2} ( \vec{r} )}{{c}^{2}} \frac{{\partial }^{2}}{\partial {t}^{2}} Ψ ( \vec{r} , t ) = 0 \qquad ( A )$$

where n(\overline{r}) is the refractive index of the waveguide material, and c² is the square of the speed of light in a vacuum.

Substitution of Ψ(\vec{r},t)=Ψ(\vec{r})e^{iωt} for the wave function in (A) results in.

$$Δ Ψ ( \vec{r} ) + {( \frac{ω}{c} )}^{2} {n}^{2} ( \vec{r} ) Ψ ( \vec{r} ) = 0.$$

Initially, the wave is not subject to any constraints in the z direction.

If the wave propagates without any restrictions in the z direction, the wave function may, for example, be represented as follows:
Ψ(\vec{r})=Ψ(x,y)e^{-ik}^{_{z}}^{z}
where k_{z} is the wave vector in the z direction.

Ignoring the y direction, the wave function can be represented as follows:
Ψ(\vec{r})=Ψ(x)e^{-ik}^{_{z}}^{z}

In the following text, the regions in the waveguide with a different refractive index are considered separately from one another. As illustrated in FIG. 1, the waveguide has a core region R2, that is to say the mask structure element 16 with the refractive index n_{core}. Furthermore, the waveguide has surrounding regions R1, R3, that is to say the surrounding material 20, 22 with a refractive index n_{clad}. With regard to the regions R1, R2, R3 with different values of the refractive indices:
for the region R1, R3:

$$\frac{{\partial }^{2} {Ψ}_{1} ( x )}{\partial {x}^{2}} + ( {k}_{1}^{2} - {k}_{z}^{2} ) {Ψ}_{1} ( x ) = 0 ; where {k}_{1} = \frac{ω}{c} {n}_{1} \qquad ( B )$$
for the region R2:

$$\frac{{\partial }^{2} {Ψ}_{2} ( x )}{\partial {x}^{2}} + ( {k}_{2}^{2} - {k}_{z}^{2} ) {Ψ}_{2} ( x ) = 0 ; where {k}_{2} = \frac{ω}{c} {n}_{2} \qquad ( C )$$
where k₁ is the wave vector magnitude in the regions R1, R3, that is to say in the surrounding material 20, 22, and k₂ is the wave vector magnitude in the region R2, that is to say in the mask structure 16, and:
   k₁²=k₁ₓ²+k_{z}² and
   k₂²=k₂ₓ²+k_{z}²

Since k_{z} has the same value in the regions 1 and 2 and, furthermore, k_{z} continues to represent the tangential component of the wave vectors \vec{k}₁ and \vec{k}₂ on the boundary surface between the regions R1, R2 and R3, then:

$${k}_{1 z} = \frac{ω}{c} {n}_{1} cos {θ}_{2} and {k}_{2 z} = \frac{ω}{c} {n}_{2} cos {θ}_{2}$$

$${k}_{1 z} {=}^{!} {k}_{2 z} = {k}_{z} .$$

The above relationship directly results in, for example, the law of refraction on the boundary surface between the regions R1 and R2, that is to say between the surrounding material 20 and the mask structure element 16:

$$\frac{ω}{c} {n}_{1} cos {θ}_{1} = \frac{ω}{c} {n}_{2} cos {θ}_{2} ⇔ {n}_{1} cos {θ}_{1} = {n}_{2} cos {θ}_{2} \qquad ( D )$$

FIG. 2 shows a schematic view of the wave vector k_{z} and of the wave vectors k₁ₓ, k₂ₓ, of the electromagnetic radiation in the regions R1 and R2, that is to say the wave vector in the surrounding material 20 and the wave vector in the mask structure element 16. If the angles of the respective wave vectors k₁ₓ and k₂ₓ are considered with respect to the perpendicular to the boundary surface, that is to say the angle θ₁ for k₁ₓ and the angle θ₂ for k₂ₓ, then, from (D) and using:
φ₁=90°−θ₁ and
φ₂=90°−θ₂:
the
   n₁ sinφ₁=n₂ sin φ₂.

Furthermore, equations (B) and (C) can be simplified to form:

$$\begin{matrix}\frac{{\partial }^{2} {Ψ}_{1}}{\partial {x}^{2}} + {k}_{1 x}^{2} {Ψ}_{1} = 0 ; {k}_{1 x}^{2} = {k}_{1}^{2} - {k}_{z}^{2} ( Region 1 , 3 ) & ( E ) \\ \frac{{\partial }^{2} {Ψ}_{2}}{\partial {x}^{2}} + {k}_{2 x}^{2} {Ψ}_{2} = 0 ; {k}_{2 x}^{2} = {k}_{2}^{2} - {k}_{z}^{2} ( Region 2 ) . & ( F )\end{matrix}$$

From FIG. 2, it is evident that:

$${k}_{1 x} = \frac{ω}{c} {n}_{1} sin {θ}_{1}$$

$${k}_{2 x} = \frac{ω}{c} {n}_{2} sin {θ}_{2}$$

Depending on the refractive index, the solutions for (E) and (f) are:
for the region R1 with the refractive index n₁:

$$Ψ = {A}_{1} {ⅇ}^{{\overline{k}}_{1} x}$$

$$\frac{\partial Ψ}{\partial x} = {\overline{k}}_{1} {A}_{1} {ⅇ}^{{\overline{k}}_{1} x}$$
for the region R2 with the refractive index n₂:

$$Ψ = {A}_{2} {ⅇ}^{- ⅈ {k}_{2} x} + {B}_{2} {ⅇ}^{ⅈ {k}_{2} x}$$

$$\frac{\partial ψ}{\partial x} = - ⅈ {k}_{2} {A}_{2} {ⅇ}^{- ⅈ {k}_{2} x} + ⅈ {k}_{2} {B}_{2} {ⅇ}^{ⅈ {k}_{2} x}$$
for the region R3 with the refractive index n1:

$$Ψ = {A}_{3} {ⅇ}^{- {\overline{k}}_{3} x}$$

$$\frac{\partial Ψ}{\partial x} = - {\overline{k}}_{3} {A}_{3} {ⅇ}^{- {\overline{k}}_{3} x}$$

In order to assist clarity, the index (x) is omitted in the following text. Thus, in the following text:
k₁ₓ=k₁, k₂ₓ=k₂, k₃ₓ=k₃.

In this case, it has been assumed—as will be confirmed later by the constraints—that the wave runs without any reflections from left to right in the region R1, that is to say in the surrounding material 20. The wave type in the region R1 is thus an exponentially attenuated wave. The wave type in the region R1 is restricted by the constraint at

$$+ \frac{{d}_{0}}{2} and \frac{{d}_{0}}{2}$$

and comprises a component which runs to the right, and a component which runs to the left, where d₀ corresponds to the extent of the core region R2 in the x direction, and d_{xcore} corresponds to the extent of the mask structure element 16 in the x direction, that is to say d₀=d_{xcore}.

For planar waves, the continuous nature of the amplitude and the first derivative on the boundary surface 18 at the positions

$$+ \frac{{d}_{0}}{2} and - \frac{{d}_{0}}{2} :$$

$$\begin{matrix}{ψ}_{1} {\vert}_{- \frac{{d}_{0}}{2}} = {ψ}_{2} {\vert}_{- \frac{{d}_{0}}{2}} ; & ( I ) \\ \frac{\partial {ψ}_{1}}{\partial χ} {\vert}_{- \frac{{d}_{0}}{2}} = \frac{\partial {ψ}_{2}}{\partial χ} {\vert}_{- \frac{{d}_{0}}{2}} & ( II ) \\ {ψ}_{2} {\vert}_{+ \frac{{d}_{0}}{2}} = {ψ}_{3} {\vert}_{+ \frac{{d}_{0}}{2}} & ( III ) \\ \frac{\partial {ψ}_{2}}{\partial χ} {\vert}_{+ \frac{{d}_{0}}{2}} = \frac{\partial {ψ}_{3}}{\partial χ} {\vert}_{+ \frac{{d}_{0}}{2}} & ( IV )\end{matrix}$$

Substitution of the specific wave function results in:

$$\begin{matrix}{A}_{1} {ⅇ}^{- {\overline{k}}_{1} \frac{{d}_{0}}{2}} = {A}_{2} {ⅇ}^{ⅈ {\overline{k}}_{2} \frac{{d}_{0}}{2}} + {B}_{2} {ⅇ}^{- ⅈ {k}_{1} \frac{{d}_{0}}{2}} & ( I ) \\ {\overline{k}}_{1} {A}_{1} {ⅇ}^{- {\overline{k}}_{1} \frac{{d}_{0}}{2}} = - i {k}_{2} {A}_{2} {ⅇ}^{ⅈ {k}_{2} \frac{{d}_{0}}{2}} + {ik}_{2} {B}_{2} {ⅇ}^{- ⅈ {k}_{2} \frac{{d}_{0}}{2}} & ( II ) \\ {A}_{3} {ⅇ}^{- {\overline{k}}_{2} \frac{{d}_{0}}{2}} = {A}_{2} {ⅇ}^{- ⅈ {k}_{2} \frac{{d}_{0}}{2}} + {B}_{2} {ⅇ}^{ⅈ {k}_{2} \frac{{d}_{0}}{2}} & ( III ) \\ - {\overline{k}}_{3} {A}_{3} {ⅇ}^{- {\overline{k}}_{2} \frac{{d}_{0}}{2}} = - {ik}_{2} {A}_{2} {ⅇ}^{- ⅈ {k}_{2} \frac{{d}_{0}}{2}} + ⅈ {k}_{2} {B}_{2} {ⅇ}^{ⅈ {k}_{2} \frac{{d}_{0}}{2}} & ( IV )\end{matrix}$$

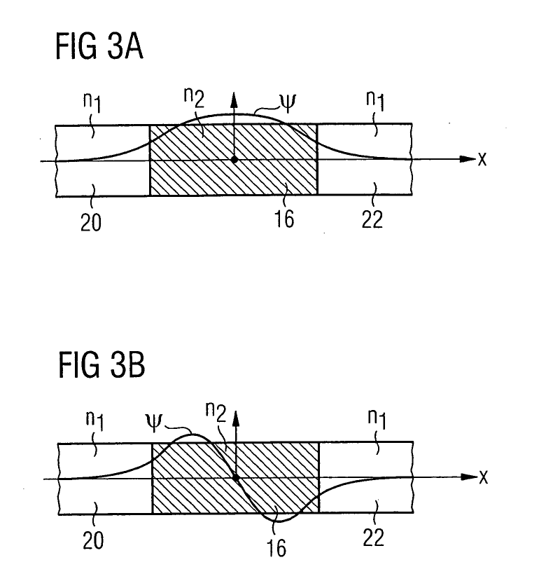

On the basis of symmetry considerations, which are illustrated in FIGS. 3a and 3b, the modes in the waveguide can illustrated in FIGS. 3a and 3b, the modes in the waveguide can be determined as follows:

Symmetrical mode (see FIG. 3a):

$$\begin{matrix}{A}_{1} = {A}_{3} ; & \\ {\overline{k}}_{1} = {\overline{k}}_{3} ⇒ & \\ {A}_{1} {ⅇ}^{- {\overline{k}}_{1} \frac{{d}_{0}}{2}} = {A}_{2} {ⅇ}^{ⅈ {k}_{2} \frac{{d}_{0}}{2}} + {B}_{1} {ⅇ}^{- ⅈ {k}_{1} \frac{{d}_{0}}{2}} ⇒ & ( I ) \\ {A}_{1} {ⅇ}^{- {\overline{k}}_{1} \frac{{d}_{0}}{2}} = {A}_{2} {ⅇ}^{- ⅈ {k}_{2} \frac{{d}_{0}}{2}} + {B}_{2} {ⅇ}^{ⅈ {k}_{2} \frac{{d}_{0}}{2}} & ( III )\end{matrix}$$

from (I) (III), it follows that: A₂=B₂

$$\begin{matrix}⇒ {\overline{k}}_{1} {A}_{1} {ⅇ}^{- {\overline{k}}_{1} \frac{{d}_{0}}{2}} = + i {k}_{2} {A}_{2} ( {ⅇ}^{- ⅈ {k}_{2} \frac{{d}_{0}}{2} - {ⅇ}^{ⅈ {k}_{2} \frac{{d}_{0}}{2}}} ) & ( II ) \\ ⇒ {A}_{1} {ⅇ}^{- {\overline{k}}_{1} \frac{{d}_{0}}{2}} = {A}_{2} ( {ⅇ}^{ⅈ {k}_{2} \frac{{d}_{0}}{2}} - {ⅇ}^{- ⅈ {k}_{2} \frac{{d}_{0}}{2}} ) & ( I )\end{matrix}$$
from substitution of (I) in (II) it follows that:

$${\overline{k}}_{1} {A}_{2} ( {ⅇ}^{ⅈ {k}_{2} \frac{{d}_{0}}{2}} - {ⅇ}^{- ⅈ {k}_{2} \frac{{d}_{0}}{2}} ) = ⅈ {k}_{2} {A}_{2} ( {ⅇ}^{- ⅈ {k}_{2} \frac{{d}_{0}}{2}} - {ⅇ}^{ⅈ {k}_{2} \frac{{d}_{0}}{2}} ) \\ ⇔ {\overline{k}}_{1} \underbrace{\frac{1}{2} ( {ⅇ}^{ⅈ {k}_{2} \frac{{d}_{0}}{2}} - {ⅇ}^{- ⅈ {k}_{2} \frac{{d}_{0}}{2}} )}_{cos ( {k}_{2} \frac{{d}_{0}}{2} )} = {k}_{2} \underbrace{\frac{1}{2 i} ( {ⅇ}^{ⅈ {k}_{2} \frac{{d}_{0}}{2}} - {ⅇ}^{ⅈ {k}_{2} \frac{{d}_{0}}{2}} )}_{sin ( {k}_{2} \frac{{d}_{0}}{2} )} \\ ⇒ {k}_{1} = {k}_{2} tan ( {k}_{2} \frac{{d}_{0}}{2} ) \qquad ( G )$$

Asymmetric mode (see FIG. 3b):
A₁=−A₃; \overline{k}₁=\overline{k}₃
an analogous calculation results in: A₂=−B₂
and after reorganization:

$${\overline{k}}_{1} = \frac{- {k}_{2}}{tan ( {k}_{2} \frac{{d}_{0 }}{2} )} \qquad ( H )$$

### SUMMARY

For symmetrical modes:

$${\overline{k}}_{1} = {k}_{2} tan ( {k}_{2} \frac{{d}_{0}}{2} ) \\ {ψ}_{1} = {A}_{1} {ⅇ}^{{\overline{k}}_{1} x} = {ψ}_{0 clad} {ⅇ}^{{\overline{k}}_{1} x} \\ {ψ}_{2} = {A}_{2} \cdot 2 cos ( {k}_{2} \frac{{d}_{0}}{2} ) = {ψ}_{0 core} cos ( {k}_{2} \frac{{d}_{0}}{2} ) \\ {ψ}_{3} = {A}_{1} {ⅇ}^{{\overline{k}}_{1} x} = {ψ}_{0 clad} {ⅇ}^{{\overline{k}}_{1} x} \qquad ( I )$$

For asymmetric modes:

$${\overline{k}}_{1} = \frac{- {k}_{2}}{tan ( {k}_{2} \frac{{d}_{0}}{2} )} \\ {ψ}_{1} = {A}_{1} {ⅇ}^{{\overline{k}}_{1} x} = {ψ}_{0 clad} {ⅇ}^{{\overline{k}}_{1} x} \\ {ψ}_{2} = 2 i {A}_{2} sin ( {k}_{2} \frac{{d}_{0}}{2} ) = {ψ}_{0 core} sin ( {k}_{2} \frac{{d}_{0}}{2} ) \\ {ψ}_{3} = - {A}_{1} {ⅇ}^{{\overline{k}}_{1} x} = - {ψ}_{0 clad} {ⅇ}^{- {\overline{k}}_{1} x} \qquad ( J )$$

Further analysis of the wave vectors \overline{k}₁ and k₂ in the formulae (I) and (J):

As described above, \overline{k}₁ and k₂ are the real x components of the wave vectors in the regions 1 and 2:
\overline{k}₁→\overline{k}₁ₓ;
\overline{k}₂→\overline{k}₂ₓ;

In the region 2: k₂²=k₂ₓ²+k_{2z}² [symbol] k_{z}²−k₂ₓ²;

In the region 1: k₁²=k₁ₓ²+k_{z}² [symbol] [symbol] k₁ₓ²=k₁²−k_{z}² [symbol] [symbol] k₁ₓ²=−k_{z}²+k₁² [symbol] [symbol] k₁ₓ²=−(k_{z}²−kₜ²) [symbol] [symbol] (ik₁ₓ)²=(k_{z}²−kₜ²)
k₁ₓ is complex since the wave is exponentially attenuated in the region 1. Thus,
   k_{z}²>k₁²>k₁ₓεC.

The wave vector \overline{k}₁x is therefore used instead of (ik₁ₓ):

$${ik}_{1 x}^{2} {=}^{!} {( {\overline{k}}_{1 x} )}^{2} = {k}_{z}^{2} - {k}_{1}^{2} ;$$

from the region 2, it is known that k_{z}²=k₂²−k₂ₓ² [symbol] \overline{k}₁ₓ=\sqrt{k₂³−k₁²−k₂ₓ²}

Furthermore, from (B) and (C), it is known that:

$${k}_{2}^{2} = {( \frac{ω}{c} )}^{2} {n}_{2}^{2} and {k}_{1}^{2} = {( \frac{ω}{c} )}^{2} {n}_{1}^{2}$$

This results in the equation (K):

$${\overline{k}}_{1 x} = \sqrt{{( \frac{ω}{c} )}^{2} ( {n}_{2}^{2} - {n}_{1}^{2} ) - {k}_{2 x}^{2}}$$

$$\frac{ω}{c} = \frac{2 π f}{λ} = \frac{2 π}{λ} ; since λ \cdot f = c$$

$$thus \text{:}$$

$${\overline{k}}_{1 x} = \sqrt{{( \frac{2 π}{λ} )}^{2} ( {n}_{2}^{2} - {n}_{1}^{2} ) - {k}_{2 x}^{2}}$$

$${n}_{2} > {n}_{1}$$

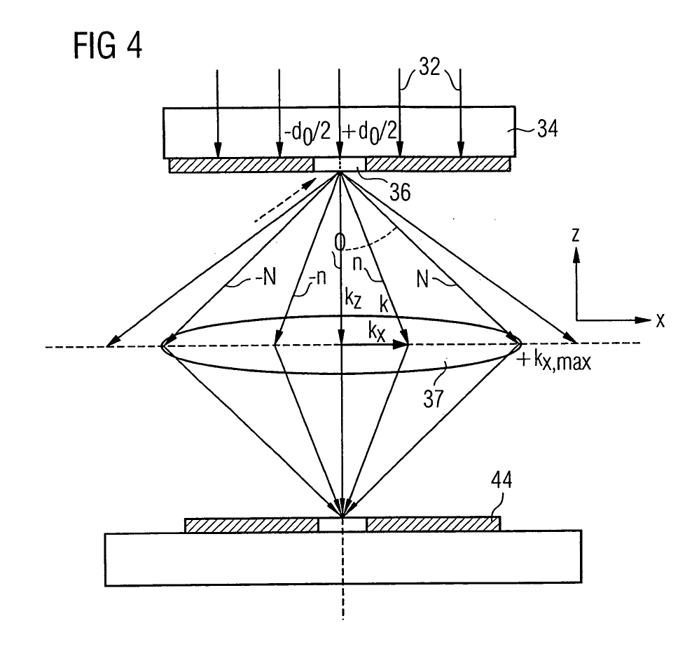

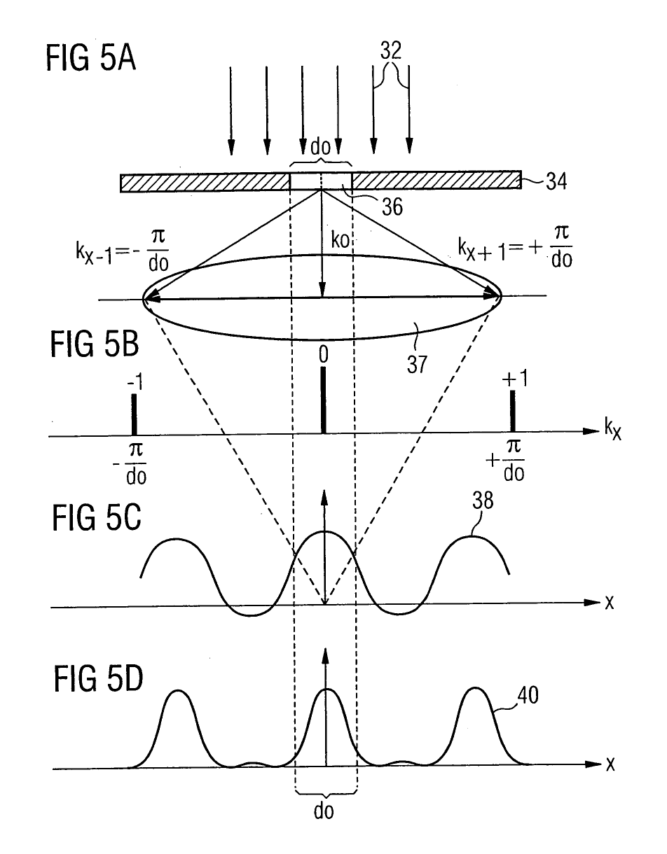

The resolution factor k₁ will be described in detail in the following text with reference to FIGS. 4, 5 and 6. FIG. 4 shows, in detail, the diffraction of electromagnetic radiation 32 on a binary mask 34, in particular on a single gap 36. FIG. 4 shows a large number of diffraction orders. The diffraction orders up to the degree N are received and imaged by using a lens system 37. FIG. 5a shows, schematically, an arrangement of a single gap 36 and, schematically, 0-order and 1st order diffractions of the electromagnetic radiation 32 as it passes through the binary mask 34, that is to say as it passes through the single gap 36 in the binary mark 34. Diffraction on the single gap 36 results in the following Fourier components:

$$M ( {k}_{x} ) = \sqrt{\frac{2}{π}} \frac{sin ( {k}_{x} \frac{{d}_{0}}{2} )}{{k}_{x}}$$

The maxima occur at kₓ=0 and at

$$\vert sin ( {k}_{x} \frac{{d}_{0}}{2} ) \vert = 1 ⇔ {k}_{x} \frac{{d}_{0}}{2} = ( 2 n - 1 ) \frac{π}{2} \\ ⇒ {k}_{x} = ( 2 n - 1 ) \frac{π}{{d}_{0}} ; n = 1 , 2 , 3 , … , N .$$

In consequence, the smaller the gap d₀ of the single gap 36, the greater kₓ becomes for a fixed n. With a single gap 36 and diffraction in air, kₓ becomes:

$${κ}_{χ} ≅ \underbrace{\frac{ω}{c}}_{\frac{2 π}{λ}} {n}_{Luft} sin θ \\ ⇒ {κ}_{χ} = \frac{2 π}{λ} {n}_{Air} sin θ = ( 2 n - 1 ) \frac{π}{{d}_{0}} ;$$

If the lens 37 actually still receives the first order, that is to say n=1:

$${k}_{x} = \frac{2 π}{λ} {n}_{air} sin θ = \frac{π}{{d}_{0}} \\ ⇔ {d}_{0} = \frac{1}{2} \frac{λ}{{n}_{air} sin θ} \qquad ( L )$$

In the equation (L), the factor

$$\frac{1}{2}$$

is also referred to as the resolution factor k₁:

$$⇒ {d}_{0} = {k}_{1} \frac{λ}{{n}_{air} sin θ}$$

The following text explains why k₁, can assume the ideal value of 0.25 for a phase shifter mask 42:

The Fourier components of the simple binary mask 34 are

$$( 2 n - 1 ) \frac{π}{{d}_{0}} ,$$

that is to say M(kₓ) can be represented as approximately as follows:

$$M ( {k}_{x} ) \approx δ ( {k}_{x} ) + {{\sum }_{n = - N}^{n = N}}_{n \neq 0} \frac{sin ( n \frac{π}{2} )}{n \frac{π}{2}} δ ( {k}_{x} - n \frac{2 π}{2 {d}_{0}} ) \qquad ( M )$$

δ( ) is in this case the delta distribution.

FIG. 5b shows a schematic illustration of the above Fourier components for a conventional binary mask as a function of kₓ.

For large diffraction angles (large kₓ, small structures) and a lens system 37 which just still receives the +1 and −1 diffraction orders, (M) can be simplified to:

$$M ( {k}_{x} ) ≅ δ ( {k}_{x} ) + \frac{2}{π} δ ( {k}_{x} + \frac{2 π}{2 {d}_{0}} ) + \frac{2}{π} δ ( {k}_{x} - \frac{2 π}{2 {d}_{0}} )$$

The reverse transform of M(kₓ), that is to say the image function 38, is:

$${M}^{′} ( x ) = \frac{1}{\sqrt{2 π}} {\int }_{- {k}_{x} , Max}^{+ {k}_{x} , Max} M ( {k}_{x} ) {ⅇ}^{- ⅈ {k}_{x} x} ⅆ x . \qquad ( N )$$

Using the characteristics of the delta distribution, that is to say using:

$${\int }_{- ∞}^{∞} δ ( {k}_{x} - b ) F ( {k}_{x} ) ⅆ {k}_{x} = F ( b )$$

the image function 38 becomes:

$$\begin{matrix}{M}^{′} ( x ) = \frac{1}{\sqrt{2 π}} [ 1 + \frac{2}{π} {ⅇ}^{+ ⅈ \frac{π}{{d}_{0}} x} + \frac{2}{π} {ⅇ}^{- ⅈ \frac{π}{{d}_{0}} x} ] \\ = \frac{1}{\sqrt{2 π}} [ 1 + \frac{4}{π} cos \frac{π}{{d}_{0}} x ] \\ = \sqrt{\frac{2}{π}} [ \frac{1}{2} + \frac{2}{π} cos \frac{π}{{d}_{0}} x ]\end{matrix}$$

The image function 38 M(kₓ) is shown in FIG. 5c as a function of the lateral coordinate, that is to say the x coordinate. The intensity distribution 40, that is to say the square of the image function, is illustrated in FIG. 5d as a function of the lateral coordinate. The intensity distribution 40 is thus:

$$I ( x ) = {( {M}^{′} ( x ) )}^{2} = {\frac{2}{π} [ \frac{1}{2} + \frac{2}{π} cos \frac{π}{{d}_{0}} x ]}^{2}$$

[symbol] FIGS. 5a, 5b, 5c and 5d also show the size of the single gap 36 using dashed lines. FIGS. 4 and 5 clearly show that, for example, the image has the width d₀ on a photoreactive layer 44 (FIG. 4) on which the single gap 36 is imaged, with this width d₀ corresponding to the gap width of the mask.

Since the lens system 37 just still receives the wave vectors

$${k}_{x - 1} = - \frac{π}{{d}_{0}} and {k}_{x + 1} = \frac{π}{{d}_{0}} ,$$

this once again results, with

$${k}_{x} ≅ \frac{2 π}{λ} {n}_{air} sin θ ,$$

in the condition

$${d}_{0} = 0.5 \frac{λ}{{n}_{air} sin θ}$$

(corresponding to the diffraction on the single gap).

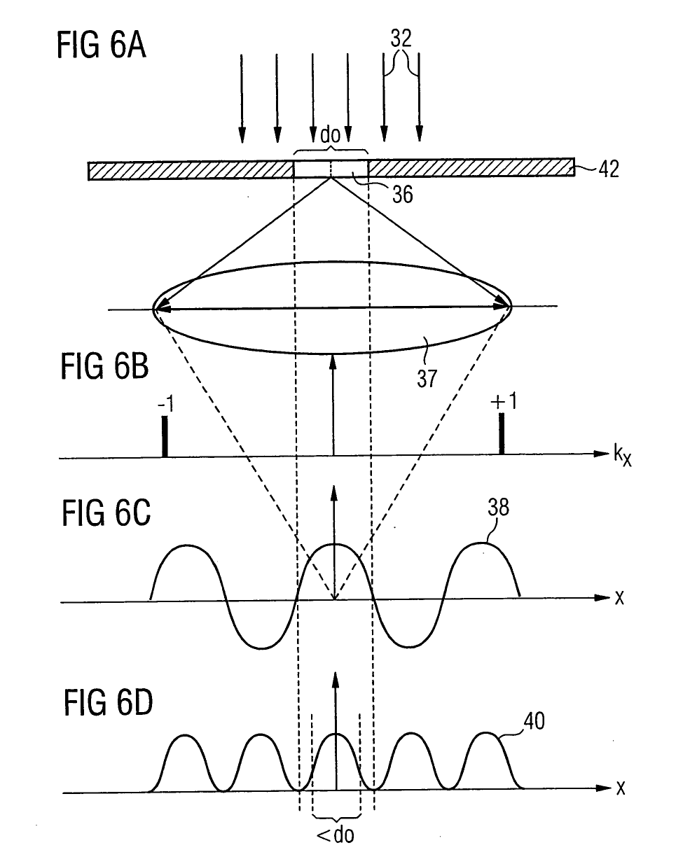

Analogously to FIG. 5a, FIG. 6a shows, schematically, a phase shifter mask 42. The 0-order diffraction is canceled out in the phase shifter mask 42 as a result of delay time differences in the z direction. FIG. 6b shows M(kₓ) as a function of kₓ, the first term δ(kₓ) disappears as a result of the cancellation of the 0-order diffraction, and the formula is thus as follows:

$$M ( {k}_{x} ) = + {\sum }_{{n = - N}_{n \neq 0}}^{n = N} \frac{sin ( n \frac{π}{2} )}{n \frac{π}{2}} δ ( {k}_{x} - n \frac{2 π}{2 {d}_{0}} )$$

If the lens system 37 just still receives the +1 and −1s order diffraction, the formula becomes:

$$M ( {k}_{x} ) ≅ \frac{2}{π} δ ( {k}_{x} + \frac{2 π}{{d}_{0}} ) + \frac{2}{π} δ ( {k}_{x} - \frac{2 π}{{d}_{0}} )$$

An analogous situation applies to the reverse transform, that is to say to the image function 38:

$${M}^{′} ( x ) = \frac{1}{\sqrt{2 π}} [ \frac{2}{π} {ⅇ}^{ⅈ \frac{π}{{d}_{0}} x} + \frac{2}{π} {ⅇ}^{- ⅈ \frac{π}{{d}_{0}} x} ] = \sqrt{\frac{2}{π} [ \frac{2}{π} cos \frac{π}{{d}_{0}} x ]} , and$$

The image function 38 is shown in FIG. 6c as a function of the lateral coordinate (see FIG. 5c). The intensity distribution 40 of this:

$$I ( x ) = {\vert {M}^{′} ( x ) \vert}^{2} = {\frac{2}{π} [ \frac{2}{π} cos \frac{π}{{d}_{0}} x ]}^{2}$$

is illustrated in FIG. 6d as a function of the lateral coordinate (x coordinate). Furthermore, dashed lines are used to indicate the width d₀ of the single gap 36 in FIGS. 6a, 6b, 6c and 6d. As is also evident from FIG. 6d, the intensity distribution 40, for example on the photoreactive layer 44 (FIG. 4), has a width of less than d₀, which is equivalent to an improvement in resolution.

This improvement in resolution is taken into account by choosing the resolution factor k₁ to be less than 0.5. An optimum phase shifter mask allows k₁ to reach approximately 0.25.

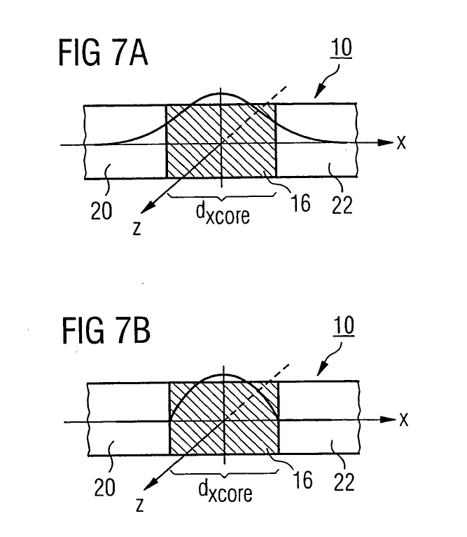

The method of operation of one example of a mask device 10, as is used in one preferred embodiment variant of the method according to the invention, will be described in the following text with the assistance of FIGS. 7a and 7b.

The above detailed description of the method of operation of a waveguide is used here. In this case k₁ corresponds to the complex wave vector in the surrounding material 20, 22 and k₂ corresponds to the complex wave vector in the mask structure element. Furthermore, n₁=n_{xclad}, n₂=n_{core}, and d₀=d_{xcore}.

It is evident from the above description of the function of a waveguide that, for lateral mode selection, that is to say for definition of discrete k₂ₓ=k_{xcore}−wave vectors, the dimension in the z direction is of secondary importance. On first sight, this is contrary to intuition if one considers the expression “waveguide”. The structure is used to select the modes and the associated lateral wave vectors via lateral mask dimensioning (d₀) and on the basis of a suitable choice of the refractive indices in the already defined regions. There is no need for internal multiple reflections in the waveguide for “transportation” of the wave.

The following text considers a symmetrical mode in the waveguide. As is shown in FIG. 7a, the wave is exponentially attenuated laterally on the basis of Ψ_{0clad}e^{-\overline{k}}^{_{xclad}}^{x} in the surrounding material. On the basis of the mode selection conditions for symmetrical modes (see equation (I)), the permissible modes in the mask structure element 16 of the waveguide are:

$${\overline{k}}_{xclad} = {k}_{xcore} tan ( {k}_{xcore} \frac{{d}_{xcore}}{2} )$$

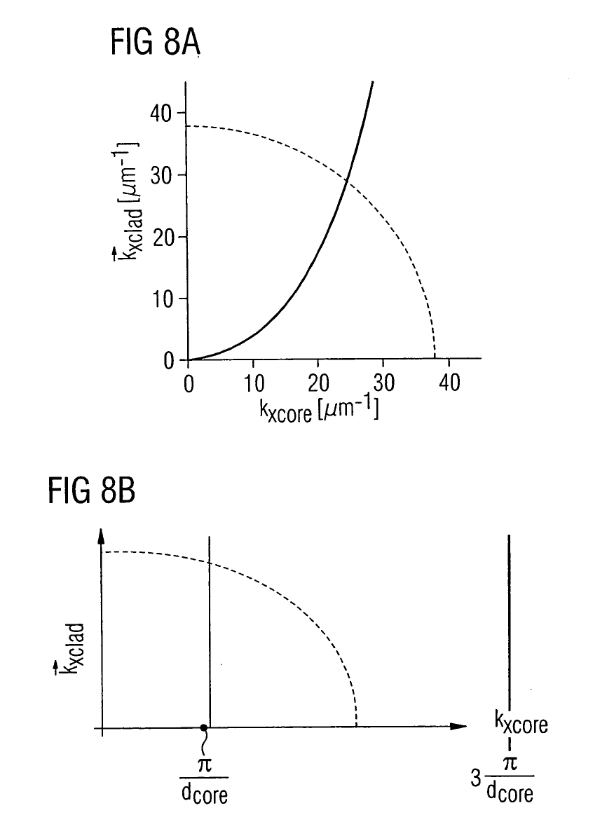

The permissible modes are found numerically/graphically, as shown in FIG. 8a. FIG. 8a shows \overline{k}_{xclad} as a function of k_{xcore}, so that:

$${\overline{k}}_{xclad} = \sqrt{{( \frac{2 π}{λ} )}^{2} ( {n}_{core}^{2} - {n}_{xclad}^{2} ) - {k}_{xcore}^{2}} .$$

The graphical solution shows (see FIG. 8a) that the permissible lateral mode, as is illustrated in FIG. 7a, lies close to the vertical line at which

$$tan ( {k}_{xcore} \frac{{d}_{xcore}}{2} ) -> \pm ∞ .$$

For illustrative purposes, FIG. 7b shows a variant, that is to say a limit case for the mask device 10, in which the surrounding material 20, 22 is impermeable or opaque for the wave. In this case, the wave attenuation is so great that \overline{k}_{xclad} tends to ∞. Analogously to FIG. 8a, FIG. 8b shows \overline{k}_{xclad} as a function of k_{xcore}. Thus:

$${\overline{k}}_{xclad} = {k}_{xcore} tan ( {k}_{xcore} \frac{{d}_{xcore}}{2} ) -> ∞ \\ ⇔ cos ( {k}_{xcore} \frac{{d}_{xcore}}{2} ) -> 0 \\ ⇔ {k}_{xcore} \frac{{d}_{xcore}}{2} = ( 2 n - 1 ) \frac{π}{2} \\ ⇔ {k}_{xcore} = ( 2 n - 1 ) \frac{π}{2}$$

As expected, this special case corresponds to the modes of a conventional binary mask 34 (see FIGS. 5, 8b,). In the case of a binary mask 34, therefore in the case of diffraction on a single gap 36, the dimensioning in the z direction is likewise irrelevant.

However, with regard to the dimensioning of the mask structure elements in the z direction, lengths should be avoided which lead to reflection losses in the inputting of the wave into the mask and the outputting of the wave from the mask, that is to say care should be taken to avoid thickness ratios leading to path differences of integer multiples of λ/4.

It is evident from the equations (I) and (J) that, in the case of the mask device according to the preferred embodiment variant of the present invention, k_{xcore}=0 cannot be a solution unless \overline{k}_{xclad} is infinitely high. This is ensured as long as the regions R1 and R3 (that is to say the surrounds of a waveguide in the optical band) remain roughly transparent−in contrast to the binary mask 34.

As a result of the lateral structuring and the choice of the refractive indices n_{xclad} and n_{core}, mask devices according to the present invention advantageously have no 0-order diffraction.

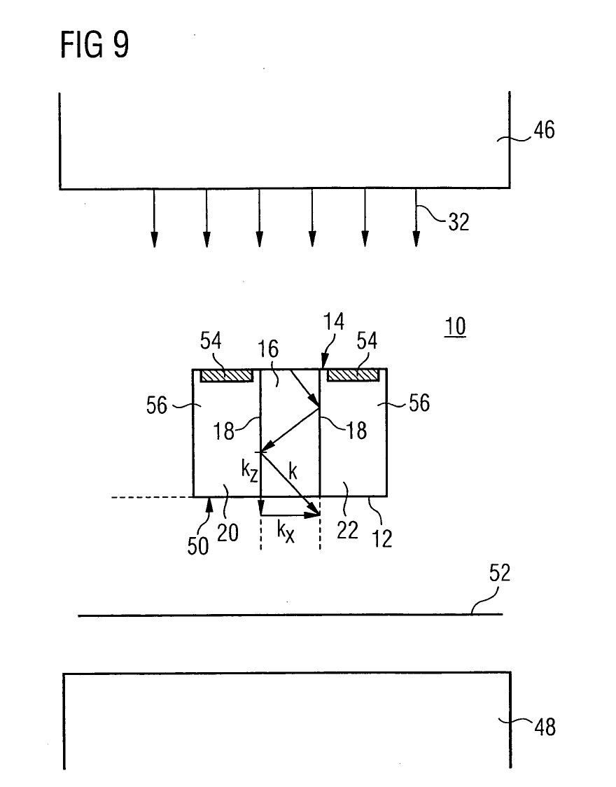

A further preferred embodiment variant of the method according to the present invention will be described with reference to FIG. 9. In this case, the surrounding material 20, 22 is preferably air, that is to say n_{xclad}=1. Furthermore, the mask device 10 has a large number of mask structure elements 16. Each of the mask structure elements 16 is essentially cuboid. The surfaces 18 run essentially at right angles to the plate plane 12 of the mask device 10 which is in the form of a plate, with all of the surfaces of the mask device 10 being essentially planar surfaces. In other words, the surfaces 18 are essentially at right angles to one another and are essentially at right angles to the plate plane 12 of the mask device 10, that is to say at right angles to the xy plane. Furthermore, the mask structure elements 16 may be superimposed, so that regions of a mask structure element 16 also include, for example, regions of another mask structure element 16.

Furthermore, the mask device 10 is arranged during operation in the beam path between a radiation source 46 and a photoreactive layer 48. Electromagnetic radiation 32 which arrives at the mask device 10 essentially parallel to the z direction from the radiation source 46 passes through the mask device 10, in particular the mask structure element 16. The electromagnetic radiation 32 preferably arrives on an input face 14 of the mask device 10. The electromagnetic radiation 32 passes into the mask device 10, preferably into the mask structure element 16 of the mask device 10. During the propagation of the electromagnetic radiation 32 through the mask structure element 16, the waveguide characteristics described above apply. After passing through the mask structure element 16, the electromagnetic radiation 32 is emitted on the output face 50 of the mask device 10 and is imaged by a lens system 52 on the photoreactive layer 48.

On the basis of the waveguide characteristics, the electromagnetic radiation 32 can essentially pass only through the mask structure elements 16 when passing through the mask device 10, since it is essentially completely attenuated in the surrounding material 20, 22. The structure of the mask device 10 is thus essentially transferred to the photoreactive layer 48.

The waveguide characteristics essentially apply only when the electromagnetic radiation 32 arrives essentially on the mask structure elements 16 or additionally on small areas, which essentially surround the mask structure elements 16, essentially in the immediate vicinity of the mask structure elements 16. The expression “in the immediate vicinity” preferably means that areas of the surrounding material 20, 22 on which electromagnetic radiation 32 arrives are no further away from the mask structure element 16 than a small number of multiples of the wavelength of the electromagnetic radiation 32.

Furthermore, the input face 14 of the mask device 10, which is essentially in the form of a plate, is preferably essentially completely illuminated with electromagnetic radiation 32. In order that no electromagnetic radiation 32 passes through in areas of the surrounding material 20, 22 which are further away from a mask structure element 16 than a small number of multiples of the wavelength, these areas are preferably covered with a cover device 54. The cover device 54 is preferably composed of a material which is essentially opaque to the electromagnetic radiation 32. The cover device 54 preferably has essentially the same structure as the mask device 10 in a plan view, that is to say viewed in a direction parallel to the z direction, with the mask structure elements 16 essentially being cut out. Only the surrounding material 20, 22 is essentially shadowed or covered by the cover device 54.

If the surrounding material 20, 22 is, for example, air, then the cover device 54 can essentially be fitted to the output face 50 of the mask device 10 in intermediate spaces 56 between the mask structure elements 16. The cover device 54 need not necessarily be adjacent to the mask structure elements 16, since the waveguide characteristics of the mask structure elements 16 lead to electromagnetic radiation 32 which falls in the immediate vicinity (at a distance of a few wavelengths) alongside a mask structure element 16 not passing through the surrounding material 20, 22. If the surrounding material 20, 22 is, for example, a solid body, then the cover material can be introduced only into the intermediate spaces 56 between the mask structure elements 16 before the surrounding material 20, 22 is introduced into these intermediate spaces 56.

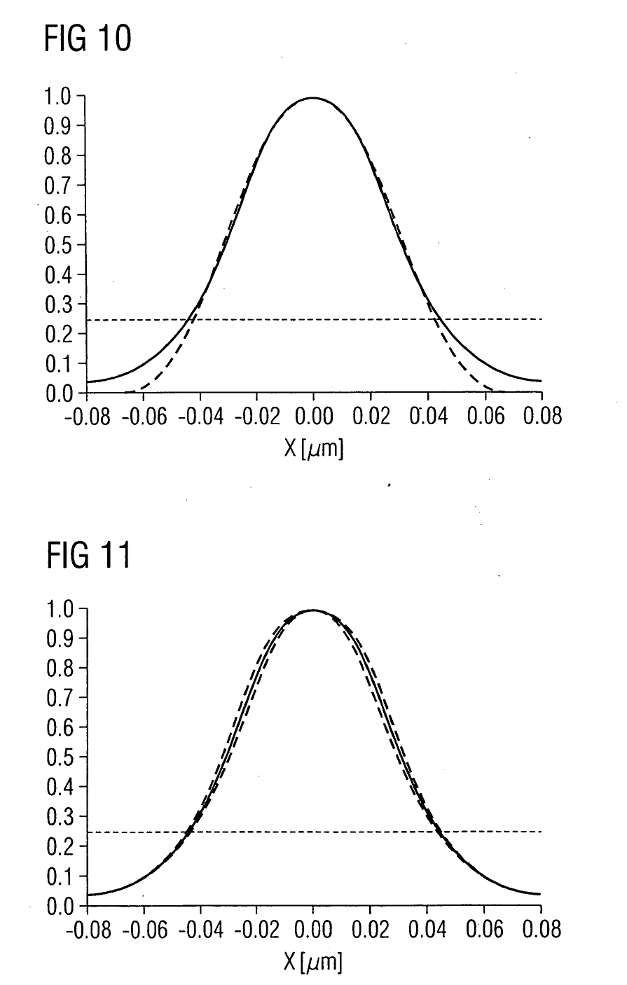

The preferred method according to the invention advantageously allows a structure to be produced with at least equivalently high resolution as that with a phase shifter mask. This is illustrated in FIG. 10. FIG. 10 shows a normalized intensity distribution plotted against the lateral position when using a mask device 10 of one preferred embodiment of the invention (solid line), and when using a conventional phase shifter mask (dashed line). The lateral position is in this case measured starting from the center point of a mask structure element or of an single gap in a binary mask in the positive and negative x directions. The horizontal dotted line corresponds to approximately 25% of the normalized intensity. As can be seen from FIG. 10, at intensity levels above 25%, the preferred method according to the present invention leads essentially to the same resolution results of those using a conventional phase shifter mask.

A further advantage of the present invention is that the size of the mask device 10 and fluctuations in this size in the z direction do not influence the waveguide characteristics, so that the mask device 10 can be produced more easily and at a lower cost than conventional phase shifter masks. Furthermore, fluctuations in the sizes in the x direction and/or in the y direction are negligible in comparison to the accuracy with which such mask devices 10 are normally produced. FIG. 11 shows the discrepancy in the intensity distribution for a discrepancy in the extent of a mask structure element 16 in the x direction of ±7%. Analogously to FIG. 10, FIG. 11 shows the normalized intensity profile with respect to the lateral position, starting from the center point of a mask structure element (solid line). Furthermore, the illustration shows the intensity profile with the dimensions of the mask structure element having been changed by ±7% in the x direction. In other words, FIG. 11 shows the resolution characteristic of a mask device with a mask structure element 16 with an extended d_{xcore} (solid line), d_{xcore}−7% d_{xcore} (dashed line) and d_{xcore}+7% d_{xcore} (dashed line). FIG. 11 shows, in contrast to a conventional phase shifter mask, that the imaging characteristics of the mask device 10 are essentially only slightly adversely affected in the event of a discrepancy in the critical dimension. Since, however, in conventional phase shifter masks, by way of example, a path length difference of precisely λ/2 is required as the interference criterion, the tolerance band in the dimensions for the critical dimension (z direction) for phase shifter masks is smaller.

In consequence, using the method according to the invention, it is possible to at least achieve a resolution such as that which can be achieved using a phase shifter mask. Mask devices 10 as are used in the method according to the present invention may, however, be produced more easily, since the critical dimension is the lateral size of the mask structure elements 16 (x size and y size), and not, as in the case of a phase shifter mask, the vertical size (z size). In fact, the resolution is governed by the high-precision lateral structuring of the mask structure elements 16 and by the choice of the refractive indices, that is to say by the choice of the materials or, for example, the mask structure element 16 and the surrounding material 20, 22.

1. A method for structure exposure of a photoreactive layer composed of a photoreactive material with electromagnetic radiation, comprising the steps of:
providing a radiation source of the electromagnetic radiation at a predetermined wavelength λ;
providing a mask device, which is essentially in a form of a plate with an input face and an output face for electromagnetic radiation, the mask device being arranged in a beam path between the radiation source and the photoreactive layer, the mask device comprising:
at least one mask structure element composed of a mask material having a predetermined refractive index n_{core} at the wavelength λ of the electromagnetic radiation; and
a surrounding material, which are adjacent to surfaces of the at least one mask structure element, which run essentially at right angles to an x direction, have a refractive index n_{xclad} at the predetermined wavelength λ of the electromagnetic radiation, with the x direction being a predetermined direction parallel to a plate plane of the mask device, and have the following relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = {k}_{xcore} tan ( {k}_{xcore} \frac{{d}_{xcore}}{2} )$$
or have the following relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = \frac{- {k}_{xcore}}{tan ( {k}_{xcore} \frac{{d}_{xcore}}{2} )} ,$$
wherein k_{xcore} is the real part of a complex wave vector of the electromagnetic radiation in the mask material in the x direction, \overline{k}_{xcore} is the imaginary part of a complex wave vector of the electromagnetic radiation in the surrounding material in the x direction, and d_{xcore} is the extent of the mask structure element in the x direction;
illuminating the input face of the mask device with the electromagnetic radiation; and
structure exposuring the photoreactive layer with electromagnetic radiation which emerges from the output face of the mask device.

2. The method as claimed in claim 1, wherein a cover device is fitted at least in places to a surface of the mask device which is adjacent to a mask structure element, wherein the cover device is essentially opaque to the electromagnetic radiation.

3. The method as claimed in claim 1, wherein the surrounding material is adjacent to surfaces of the at least one mask structure element which run essentially at right angles to a y direction, and the surrounding material has a refractive index n_{yclad} at the predetermined wavelength λ of the electromagnetic radiation with the y direction being a predetermined direction essentially at a right angle to the x direction and essentially parallel to the plane of the plate of the mask device, and the surround material has the following relationships:
$${n}_{core} > {n}_{yclad} , \\ {\overline{k}}_{yclad} = \sqrt{{( \frac{2 π}{λ} )}^{2} ( {n}_{core}^{2} - {n}_{yclad}^{2} ) - {k}_{ycore}^{2}} , and$$
$${\overline{k}}_{yclad} = {k}_{ycore} tan ( {k}_{ycore} \frac{{d}_{ycore}}{2} ) ,$$
or the relationships
$${n}_{core} > {n}_{yclad} , \\ {\overline{k}}_{yclad} = \sqrt{{( \frac{2 π}{λ} )}^{2} ( {n}_{core}^{2} - {n}_{yclad}^{2} ) - {k}_{ycore}^{2}} , and$$
$${\overline{k}}_{yclad} = \frac{- {k}_{ycore}}{tan ( {k}_{ycore} \frac{{d}_{ycore}}{2} )} ,$$
wherein k_{ycore} is the real part of a complex wave vector of the electromagnetic radiation in the mask material in the y direction, \overline{k}_{yclad} is the imaginary part of a complex wave vector of the electromagnetic radiation in the surrounding material in the y direction, and d_{ycore} is the extent of the mask structure element in the y direction.

4. The method as claimed in claim 3, wherein those surfaces of the mask structure element which run essentially at right angles to the y direction are essentially parallel to one another.

5. The method as claimed in claim 1, wherein those surfaces of the mask structure element which run essentially at right angles to the x direction are essentially parallel to one another.

6. The method as claimed in claim 1, wherein the mask structure element has an essentially rectangular cross section along a plane at right angles to the x direction.

7. The method as claimed in claim 1, wherein the mask structure element has an essentially rectangular cross section along a plane at right angles to a y direction, which is essentially at right angles to the x direction and is essentially parallel to the plate plane of the mask device which is in the form of a plate.

8. The method as claimed in claim 1, wherein the mask structure element is essentially cuboid.

9. The method as claimed in claim 1, wherein the mask structure element has an essentially circular cross section in a section plane parallel to the plate plane, and d_{xcore} is essentially equal to the diameter of the circular cross section.

10. The method as claimed in claim 9, wherein d_{ycore} is essentially equal to the diameter of the circular cross section.

11. The method as claimed in claim 1, further comprising the step of providing at least two mask structure elements at least partially merging into one another.

12. The method as claimed in claim 1, wherein the surrounding material is air.

13. The method as claimed in claim 1, wherein the photoreactive layer is a photoresist layer.

14. The method as claimed in claim 3, wherein d_{ycore} is between about 5 nm and about 100 nm, and the wavelength λ of the electromagnetic radiation is between about 100 nm and about 200 nm.

15. The method as claimed in claim 1, wherein d_{xcore} is between about 5 nm and about 100 nm, and the wavelength λ of the electromagnetic radiation is between about 100 nm and about 200 nm.

16. The method as claimed in claim 1, wherein the extent of the mask device in the plate plane is more than 100 times larger than in the direction at right angles to the mask device.

17. The method as claimed in claim 1, wherein the radiation source emits electromagnetic radiation essentially precisely at a predetermined wavelength.

18. The method as claimed in claim 1, wherein the radiation source is a laser.

19. Use of a mask device for structure exposure of a photoreactive layer composed of a photoreactive material with electromagnetic radiation, wherein the mask device
is essentially in a form of a plate,
has an input face and an output face for electromagnetic radiation,
is arranged in a beam path between a radiation source of electromagnetic radiation at a predetermined wavelength λ and the photoreactive layer,
has at least one mask structure element composed of a mask material, which has a predetermined refractive index n_{core} at the wavelength λ of the electromagnetic radiation, and
is adjacent to a surrounding material on surfaces of the at least one mask structure element which run essentially at right angles to an x direction, which surrounding material has a refractive index n_{xclad} at the predetermined wavelength λ of the electromagnetic radiation, with the x direction being a predetermined direction parallel to a plate level of the mask device, and the surrounding material has the relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = {k}_{xcore} tan ( {k}_{xcore} \frac{{d}_{xcore}}{2} )$$
or the relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = \frac{- {k}_{xcore}}{tan ( {k}_{xcore} \frac{{d}_{xcore}}{2} )} ,$$
wherein k_{xcore} is the real part of a complex wave vector of the electromagnetic radiation in the mask material in the x direction, \overline{k}_{xclad} is the imaginary part of a complex wave vector of the electromagnetic radiation in the surrounding material in the x direction, and d_{xcore} is the extent of the mask structure element in the x direction.

20. An exposure apparatus for structure exposure of a photoreactive material of a photoreactive layer with electromagnetic radiation, comprising:
a radiation source of electromagnetic radiation at a predetermined wavelength λ;
a mask device which is essentially in a form of a plate and has an input face and an output face for electromagnetic radiation, comprising:
at least one mask structure element composed of a mask material having a predetermined refractive index n_{core} at the wavelength λ of the electromagnetic radiation; and
a surrounding material which is adjacent to surfaces of the at least one mask structure element, which run essentially at right angles to an x direction, and have a refractive index n_{xclad} at the predetermined wavelength λ of the electromagnetic radiation, with the x direction being a predetermined direction parallel to a plate level of the mask device, and the surrounding material has the relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = {k}_{xcore} tan ( {k}_{xcore} \frac{{d}_{xcore}}{2} )$$
or the relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = \frac{- {k}_{xcore}}{tan ( {k}_{xcore} \frac{{d}_{xcore}}{2} )} ,$$
wherein k_{xcore} is the real part of a complex wave vector of the electromagnetic radiation in the mask material in the x direction, \overline{k}_{xclad} is the imaginary part of a complex wave vector of the electromagnetic radiation in the surrounding material in the x direction, and d_{xcore} is the extent of the mask structure element in the x direction.

21. The apparatus as claimed in claim 20, further comprising a cover device fitted at least in places to a surface of the mask device which is adjacent to a mask structure element, wherein the cover device is essentially opaque to the electromagnetic radiation.

22. The apparatus as claimed in claim 20, wherein the surrounding material is adjacent to surfaces of the at least one mask structure element which run essentially at right angles to a y direction, and the surrounding material has a refractive index n_{yclad} at the predetermined wavelength λ of the electromagnetic radiation with the y direction being a predetermined direction essentially at a right angle to the x direction and essentially parallel to the plane of the plate of the mask device, and the surrounding material has the following relationships:
$${n}_{core} > {n}_{yclad} , \\ {\overline{k}}_{yclad} = \sqrt{{( \frac{2 π}{λ} )}^{2} ( {n}_{core}^{2} - {n}_{yclad}^{2} ) - {k}_{ycore}^{2}} , and$$
$${\overline{k}}_{yclad} = {k}_{ycore} tan ( {k}_{ycore} \frac{{d}_{ycore}}{2} ) ,$$
or the relationships
$${n}_{core} > {n}_{yclad} , \\ {\overline{k}}_{yclad} = \sqrt{{( \frac{2 π}{λ} )}^{2} ( {n}_{core}^{2} - {n}_{yclad}^{2} ) - {k}_{ycore}^{2}} , and$$
$${\overline{k}}_{yclad} = \frac{- {k}_{ycore}}{tan ( {k}_{ycore} \frac{{d}_{ycore}}{2} )} ,$$
wherein k_{ycore} is the real part of a complex wave vector of the electromagnetic radiation in the mask material in the y direction, \overline{k}_{yclad} is the imaginary part of a complex wave vector of the electromagnetic radiation in the surrounding material in the y direction, and d_{ycore} is the extent of the mask structure element in the y direction.

23. The apparatus as claimed in claim 22, wherein those surfaces of the mask structure element which run essentially at right angles to the y direction are essentially parallel to one another.

24. The apparatus as claimed in claim 20, wherein those surfaces of the mask structure element which run essentially at right angles to the x direction are essentially parallel to one another.

25. The apparatus as claimed in claim 20, wherein the mask structure element has an essentially rectangular cross section along a plane at right angles to the x direction.

26. The apparatus as claimed in claim 20, wherein the mask structure element has an essentially rectangular cross section along a plane at right angles to a y direction, which is essentially at right angles to the x direction and is essentially parallel to the plate plane of the mask device which is in the form of a plate.

27. The apparatus as claimed in claim 20, wherein the mask structure element is essentially cuboid.

28. The apparatus as claimed in claim 20, wherein the mask structure element has an essentially circular cross section in a section plane parallel to the plate plane, and d_{xcore} is essentially equal to the diameter of the circular cross section.

29. The apparatus as claimed in claim 28, wherein d_{ycore} is essentially equal to the diameter of the circular cross section.

30. The apparatus as claimed in claim 20, further comprising at least two mask structure elements at least partially merging into one another.

31. The apparatus as claimed in claim 20, wherein the surrounding material is air.

32. The apparatus as claimed in claim 20, wherein the photoreactive layer is a photoresist layer.

33. The apparatus as claimed in claim 22, wherein d_{ycore} is between about 5 nm and about 100 nm, and the wavelength λ of the electromagnetic radiation is between about 100 nm and about 200 nm.

34. The apparatus as claimed in claim 20, wherein d_{xcore} is between about 5 nm and about 100 nm, and the wavelength λ of the electromagnetic radiation is between about 100 nm and about 200 nm.

35. The apparatus as claimed in claim 20, wherein the extent of the mask device in the plate plane is more than 100 times larger than in the direction at right angles to the mask device.

36. The apparatus as claimed in claim 20, wherein the radiation source emits electromagnetic radiation essentially precisely at a predetermined wavelength.

37. The method as claimed in claim 20, wherein the radiation source is a laser.

38. An exposure apparatus for structure exposure of a photoreactive material of a photoreactive layer with electromagnetic radiation, comprising:
a radiation source of electromagnetic radiation at a predetermined wavelength λ;
a mask device which is essentially in a form of a plate with an input face and an output face for electromagnetic radiation, the mask device comprising:
at least one mask structure element composed of a mask material, the mask material having a predetermined refractive index n_{core} at the wavelength of the electromagnetic radiation; and
a surrounding material, which are adjacent to surfaces of the at least one mask structure element, run essentially at right angles to an x direction, and have a refractive index n_{xclad} at the predetermined wavelength λ of the electromagnetic radiation, with the x direction being a predetermined direction parallel to a plate level of the mask device,
wherein there are predetermined mathematical relationships between the variables n_{core}, n_{xclad}, λ and d_{xcore}, with d_{xcore} being the extent of the mask structure element in the x direction.

39. A system for structure exposure of a photoreactive layer composed of a photoreactive material with electromagnetic radiation, comprising:
means for providing a radiation source of the electromagnetic radiation at a predetermined wavelength λ;
means for providing a mask device, which is essentially in a form of a plate with an input face and an output face for electromagnetic radiation, the mask device being arranged in a beam path between the radiation source and the photoreactive layer, the mask device comprising:
at least one mask structure element composed of a mask material having a predetermined refractive index n_{core} at the wavelength λ of the electromagnetic radiation; and
a surrounding material, which are adjacent to surfaces of the at least one mask structure element, which run essentially at right angles to an x direction, have a refractive index n_{xclad} at the predetermined wavelength λ of the electromagnetic radiation, with the x direction being a predetermined direction parallel to a plate plane of the mask device, and the surrounding material has the following relationships:
$${n}_{core} > {n}_{xclad} , \\ {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = {k}_{xcore} tan ( {k}_{xcore} \frac{{d}_{xcore}}{2} )$$
or have the following relationships:
$${n}_{core} > {n}_{xclad} , {\overline{k}}_{xclad} = \sqrt{{( \frac{2 π}{λ} )}^{2} ( {n}_{core}^{2} - {n}_{xclad}^{2} ) - {k}_{xcore}^{2}} , and$$
$${\overline{k}}_{xclad} = \frac{- {k}_{xcore}}{tan ( {k}_{xcore} \frac{{d}_{xcore}}{2} )} ,$$
wherein k_{xcore} is the real part of a complex wave vector of the electromagnetic radiation in the mask material in the x direction, \overline{k}_{xcore} is the imaginary part of a complex wave vector of the electromagnetic radiation in the surrounding material in the x direction, and d_{xcore} is the extent of the mask structure element in the x direction;
means for illuminating the input face of the mask device with the electromagnetic radiation; and
means for structure exposuring the photoreactive layer with electromagnetic radiation which emerges from the output face of the mask device.

40. The system as claimed in claim 39, further comprising means for providing at least two mask structure elements at least partially merging into one another.
